(19) United States
(12) Patent Application Publication
(10) Pub. No.: US 2018/0061775 A1
(43) Pub. Date: Mar. 1, 2018

(54) LOW PROFILE PASSIVE ON GLASS (PoG) DEVICE COMPRISING A DIE

(71) Applicant: QUALCOMM Incorporated, San Diego, CA (US)

(72) Inventors: Mario Velez, San Diego, CA (US); Niranjan Sunil Mudakatte, San Diego, CA (US); Changhan Yun, San Diego, CA (US); David Berdy, San Diego, CA (US); Shiqun Gu, San Diego, CA (US); Jonghae Kim, San Diego, CA (US); Chengjie Zuo, San Diego, CA (US)

(21) Appl. No.: 15/253,782

(22) Filed: Aug. 31, 2016

(51) Int. Cl. H01L 23/00; H01L 49/02; H01L 23/498; H01L 23/31; H01L 25/065; H01L 21/48; H01L 21/56; H01L 25/00

(52) U.S. Cl. CPC H01L 23/562; H01L 28/10; H01L 23/49838; H01L 23/49827; H01L 25/50; H01L 25/0655; H01L 21/4853; H01L 21/486; H01L 21/565; H01L 23/3114

(57) ABSTRACT

A device that includes a single substrate layer, a plurality of interconnects over the single substrate layer, the plurality of interconnects configured to operate as at least one passive component, a first die coupled to the single substrate layer and the plurality of interconnects, and an encapsulation layer that at least partially encapsulates the first die and the plurality of interconnects configured to operate as at least one passive component. In some implementations, the single substrate layer, the first die and the encapsulation layer comprise an overall thickness of about 225 microns (μm) or less. In some implementations, the single substrate layer comprises a thickness of about 75 microns (μm) or less.

### BACKGROUND

### Field of the Disclosure

Various features relate generally to a passive on glass (PoG device), and more specifically to a low profile passive on glass (PoG) device that includes a die.

### Background

FIG. 1 illustrates a passive on glass (PoG) device 102 and a die 104 that is mounted over a printed circuit board (PCB) 100. The PoG device 102 is coupled to the PCB 100 through a plurality of solder balls 124. The die 104 is coupled to the PCB 100 through a plurality of solder balls 144. The PoG device 102 includes a glass substrate 120 and a passive component 122. The passive component 122 is located over the glass substrate 120. The die 104 is co-planar to the PoG device 102.

One drawback of the configuration of FIG. 1 is that the die 104 and the PoG device 102 take up a lot of space on the PCB 100. In addition, the PoG device 102 has a relatively thick glass substrate 120, which makes the PoG device 102 relatively thick. The glass substrate 120 needs to be thick in order to provide structural rigidity to the PoG device 102. Typically, the glass substrate 120 has a thickness of about 250 microns (μm) or more. Anything thinner than this will increase PoG warpage. Thus, the configuration of FIG. 1 has an overall form factor that is relatively big.

Therefore, there is an ongoing need for thinner PoG devices that are less susceptible to warpage, while also provide higher density packaging.

### SUMMARY

Various features relate generally to a passive on glass (PoG) device, and more specifically to a low profile passive on glass (PoG) device that includes a die.

One example provides a device that includes a single substrate layer, a plurality of interconnects over the single substrate layer, the plurality of interconnects configured to operate as at least one passive component, a first die coupled to the single substrate layer and the plurality of interconnects, and an encapsulation layer that at least partially encapsulates the first die and the plurality of interconnects configured to operate as at least one passive component.

Another example provides an apparatus that includes a single substrate layer, a means for passive functionality located over the single substrate layer, a first die coupled to the single substrate layer and the means for passive functionality, and an encapsulation layer that at least partially encapsulates the first die and the means for passive functionality.

Another example provides a method for fabricating a device. The method provides a single substrate layer. The method forms a plurality of interconnects over the single substrate layer, where forming the plurality of interconnects forms interconnects that arc configured to operate as at least one passive component. The method couples a first die to the single substrate layer and the plurality of interconnects. The method forms an encapsulation layer that at least partially encapsulates the first die and the plurality of interconnects configured to operate as at least one passive component.

### DRAWINGS

Various features, nature and advantages may become apparent from the detailed description set forth below when taken in conjunction with the drawings in which like reference characters identify correspondingly throughout.

FIG. 1 illustrates a profile view of a passive on glass (PoG) and a die coupled to a printed circuit board (PCB).

FIG. 2 illustrates a profile view of a device that includes a passive component and a die.

FIG. 3 illustrates a plan view across of a cross section of a device that includes a passive component and a die.

FIG. 4 illustrates a plan view across a different cross section of a device that includes a passive component and a die.

FIG. 5 illustrates a plan view across of a cross section of another device that includes a passive component and a die.

FIG. 6 illustrates a profile view of another device that includes a passive component and a die.

FIG. 7 (which includes FIGS. 7A-7B) illustrates an example of a sequence for fabricating a device that includes a passive component and a die.

FIG. 8 illustrates a flow diagram of an exemplary method for fabricating a device that includes a passive component and a die.

FIG. 9 illustrates various electronic devices that may include the various integrated devices, integrated device packages, semiconductor devices, dies, integrated circuits, and/or packages described herein.

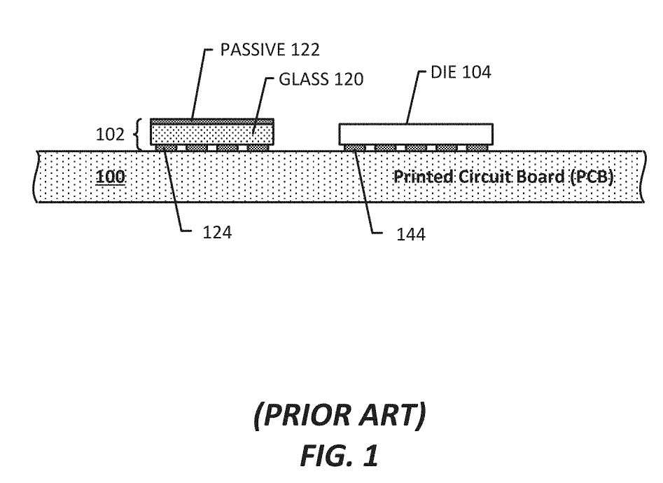

### DETAILED DESCRIPTION

In the following description, specific details are given to provide a thorough understanding of the various aspects of the disclosure. However, it will be understood by one of ordinary skill in the art that the aspects may be practiced without these specific details. For example, circuits may be shown in block diagrams in order to avoid obscuring the aspects in unnecessary detail. In other instances, well-known circuits, structures and techniques may not be shown in detail in order not to obscure the aspects of the disclosure.

### Overview

Some features pertain to a device that includes a single substrate layer, a plurality of interconnects over the single substrate layer, the plurality of interconnects configured to operate as at least one passive component (e.g., means for passive functionality), a first die coupled to the single substrate layer and the plurality of interconnects, and an encapsulation layer that at least partially encapsulates the first die and the plurality of interconnects configured to operate as at least one passive component. In some implementations, the single substrate layer, the first die and the encapsulation layer comprise an overall thickness of about 225 microns (μm) or less. In some implementations, the single substrate layer comprises a thickness of about 75 microns (μm) or less.

In some implementations, the height of the device may be defined along the Z-direction of the device, which is shown in the figures of the present disclosure. In some implementations, the Z-direction of the device may be defined along an axis between a top portion and a bottom portion of the device. The terms top and bottom may be arbitrarily assigned, however as an example, the top portion of the device may be a portion comprising an encapsulation layer, while a bottom portion of the device may be a portion comprising a redistribution portion or a plurality of solder balls. In some implementations, the top portion of the device may be a back side of the device, and the bottom portion of the device may be a front side of the device. The front side of the device may be an active side of the device. A top portion may be a higher portion relative to a lower portion. A bottom portion may be a lower portion relative to a higher portion. Further examples of top portions and bottom portions will be further described below. The X-Y directions of the device may refer to the lateral direction and/or footprint of the device. Examples of X-Y directions are shown in the figures of the present disclosure and/or further described below. In many of the figures of the present disclosure, the devices and their respective components are shown across a X-Z cross-section or X-Z plane. However, in some implementations, the devices and their representative components may be represented across a Y-Z cross-section or Y-Z plane.

In some implementations, an interconnect is an element or component of a device or package that allows or facilitates an electrical connection between two points, elements and/or components. In some implementations, an interconnect may include a trace, a via, a pad, a pillar, a redistribution metal layer, and/or an under bump metallization (UBM) layer. In some implementations, an interconnect is an electrically conductive material that may be configured to provide an electrical path for a signal (e.g., data signal, ground signal, power signal). An interconnect may be part of a circuit. An interconnect may include more than one element or component.

### Exemplary Passive on Glass (PoG) Comprising a Die

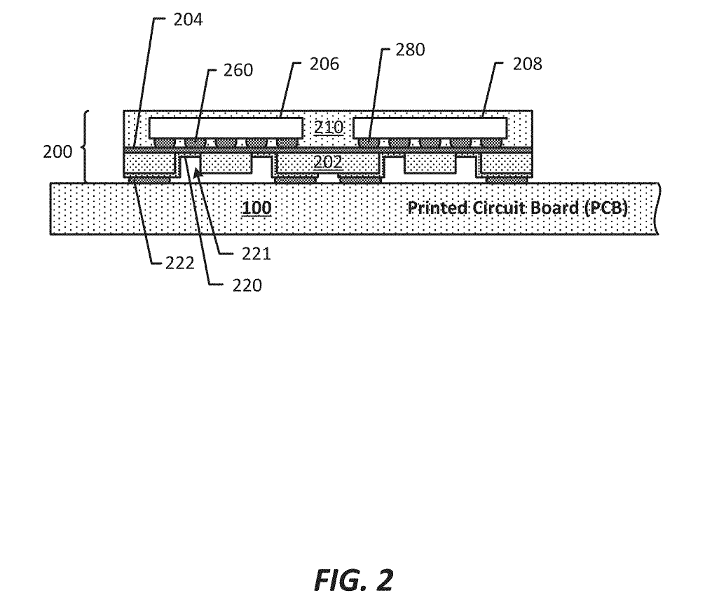

FIG. 2 illustrates a device 200 that includes a passive component and a die. The device 200 may be a passive on glass (PoG) device. The device 200 is coupled to a printed circuit board (PCB) 100 through a plurality of solder interconnects 222. The device 200 of FIG. 2 illustrates an example of a low profile device comprising at least one die. In some implementations, the device 200 is a low profile device that has an overall thickness of about 225 microns (μm) or less.

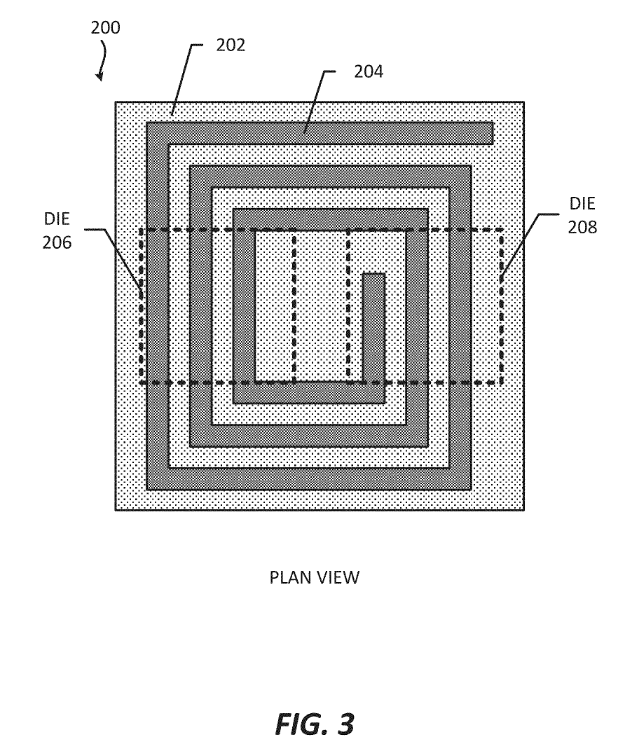

The device 200 includes a substrate 202, a plurality of interconnects 204, a first die 206, a second die 208, an encapsulation layer 210 and a plurality of substrate interconnects 220. The plurality of interconnects 204 is formed over a surface of the substrate 202. The plurality of interconnects 204 may be configured to operate as one or more passive components (e.g., means for passive functionality, inductor). For example, one or more first interconnects from the plurality of interconnects 204 may be configured to operate as a first inductor, and one or more second interconnects from the plurality of interconnects 204 may be configured to operate as a second inductor. Examples of inductors are further described and illustrated in FIGS. 3-5.

The substrate 202 is a single substrate layer or a single substrate panel. The substrate 202 may comprise glass (e.g., block of glass) or silicon (e.g., block of silicon). However, the substrate 202 may include other materials. The substrate 202 (e.g., single substrate layer, single substrate panel) is different from a substrate that includes several layers (e.g., laminated substrate that includes several dielectric layers). Thus, a single substrate layer or a single substrate panel does not include a laminated substrate formed by several dielectric layers (e.g., two or more dielectric layers) over each other. It is noted that a single substrate layer may include several materials. However, the materials in the single substrate layer or single substrate panel are not foamed by depositing several layers over each other. In some implementations, the substrate 202 has a thickness of about 75 microns (μm) or less. In sonic implementations, the substrate 202 has a thickness of about 50-75 microns (μm). Typically, a passive on glass (PoG) device will have a substrate that is much thicker than 75 microns because a thick substrate is necessary to provide structural rigidity to the PoG device. However, in the present disclosure, the substrate 202 can have a thickness of about 75 microns (μm) or less, thus providing a low profile device, due to the presence of the encapsulation layer 210. In some implementations, the combination of the substrate 202 and the encapsulation layer 210 helps provide the structural rigidity to the device 200, while still providing a low profile device. This structural rigidity helps reduces warpage in the device 200, while still providing a low profile device with a low profile substrate(e.g., low profile substrate panel).

The first die 206 is coupled to the substrate 202 through a plurality of solder interconnects 260 (e.g., solder balls, pillars and solder). The second die 208 is coupled to the substrate 202 through a plurality of solder interconnects 280 (e.g., solder balls, pillars and solder). The plurality of solder interconnects 260 and the plurality of solder interconnects 280 may include copper pillars that include solder. The first die 206 and/or the second die 208 may be flip chips. The first die 206 and the second die 208 may be separated by a spacing of about 50 microns (μm) or less.

One or more solder interconnect from the plurality of solder interconnects 260 may be coupled to the plurality of interconnects 204. Thus, one or more solder interconnect from the plurality of solder interconnects 260 may be coupled to a passive component (e.g., means for passive functionality, inductor). Similarly, One or more solder interconnect from the plurality of solder interconnects 280 may be coupled to the plurality of interconnects 204. Thus, one or more solder interconnect from the plurality of solder interconnects 280 may be coupled to a passive component (e.g., inductor).

FIG. 2 illustrates that the encapsulation layer 210 is formed over the substrate 202 and the plurality of interconnects 204. The encapsulation layer 210 at least partially encapsulates the first die 206 and the second die 208. The encapsulation layer 210 may include a mold compound and/or an epoxy fill. The encapsulation layer 210 provides a hermetical seal around the first die 206 and the second die 208. As mentioned above, the encapsulation layer 210 also helps provide structural rigidity for the device 200. In some implementations, the encapsulation layer 210 has a thickness of about 100 microns (μm) or less. In some implementations, the combination of the encapsulation layer 210, the substrate 202 and the plurality of solder interconnects 222 provide a device 200 that has a thickness of about 225 microns (μm) or less. In some implementations, the combination of the encapsulation layer 210, the substrate 202, the plurality of interconnects 204, the first die 206, the second die 208, the plurality of substrate interconnects 220 and the plurality of solder interconnects 222 provide a device 200 that has a thickness of about 225 microns (μm) or less. In some implementations, the device 200 has an overall thickness of about 175-225 microns (μm).

The substrate 202 includes a plurality of cavities 221. The plurality of cavities 221 substantially goes through the substrate 202. In some implementations, the plurality of cavities 221 goes entirely through the substrate 202. The plurality of substrate interconnects 220 is formed in the plurality of cavities 221. The plurality of solder interconnects 222 is coupled to the plurality of substrate interconnects 220. The plurality of solder interconnects 222 may include landing grid arrays (LGA). The plurality of substrate interconnects 220 may be coupled to the plurality of interconnects 204, the plurality of solder interconnects 260, and/or the plurality of solder interconnects 280. In some implementations, the plurality of substrate interconnects 220 is directly coupled to the plurality of interconnects 204. As shown in FIG. 2, in some implementations, some of the plurality of substrate interconnects 220 may be exposed. For example, portions (e.g., via portions, portions that travel vertically) of the plurality of substrate interconnects 220 that are formed in the plurality of cavities 221 may be exposed (e.g., not covered by the substrate 202).

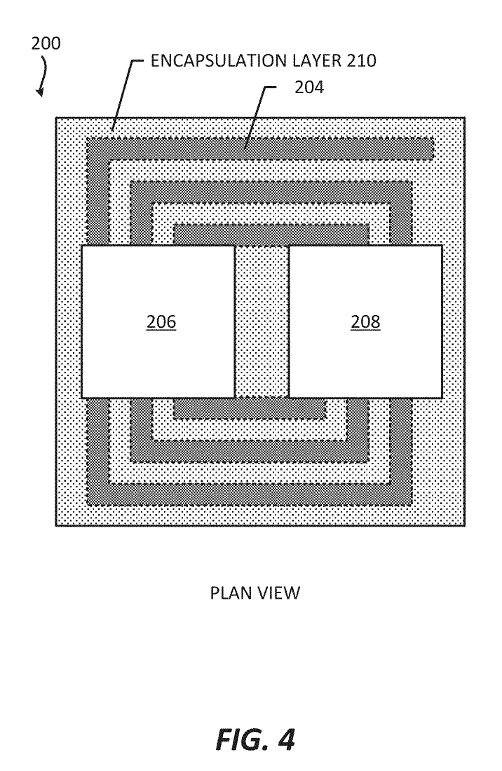

FIG. 3 illustrates a plan view of the device 200 across a cross section that includes the plurality of interconnects 204 and the substrate 202. As shown in FIG. 3, the first die 206 and the second die 208 are formed over the plurality of interconnects 204. The plurality of interconnects 204 is configured to operate as one passive component (e.g., means for passive functionality, inductor, spiral inductor). The inductor may be configured to be electrically coupled to the first die 206 and/or the second die 208. FIG. 4 illustrates a plan view of the device 200 across a cross section that includes the first die 206, the second die 208 and the encapsulation layer 210.

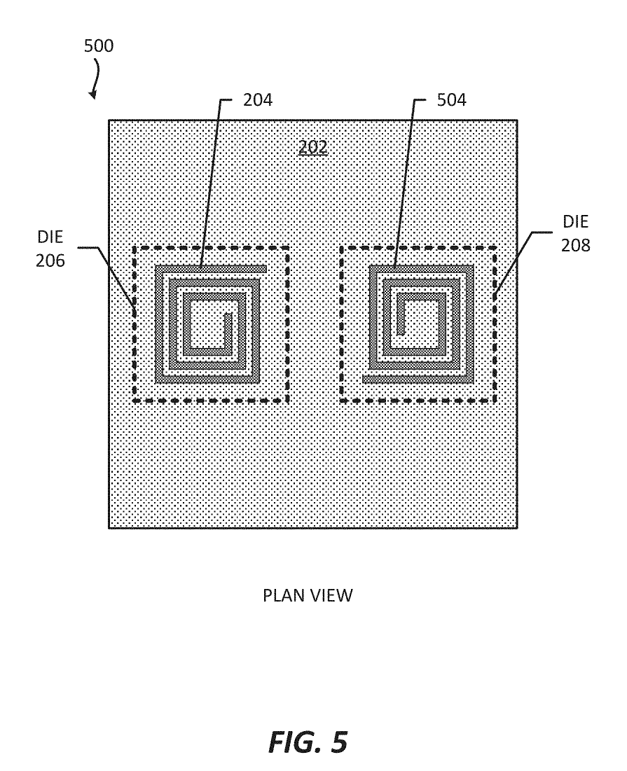

FIG. 5 illustrates a plan view of the device 500 across a cross section that includes the plurality of interconnects 204, a plurality of interconnects 504 and the substrate 202. The device 500 is similar to the device 200. The device 500 may be a passive on glass (PoG) device. The device 500 includes the plurality of interconnects 204, which is configured to operate as a first passive component (e.g., means for passive functionality, first inductor). The device 500 also includes the plurality of interconnects 504, which is configured to operate as a second passive component (e.g., means for passive functionality, second inductor). The plurality of interconnects 204 is formed over the substrate 202 and is located between the substrate 202 and the first die 206. The plurality of interconnects 504 is formed over the substrate 202 and is located between the substrate 202 and the second die 208. However, different implementations may have different configurations of the plurality of interconnects 204 and the plurality of interconnects 504. In some implementations, the first die 206 is coupled to the plurality of interconnects 204 through the plurality of solder interconnects 260. In some implementations, the second die 208 is coupled to the plurality of interconnects 504 through the plurality of solder interconnects 280. In some implementations, the device 500 is a low profile device that has an overall thickness of about 225 microns (μm) or less. In some implementations, the device 500 has an overall thickness of about 175-225 microns In some implementations, the substrate 202 may have a thickness of about 75 microns (μm) or less. In some implementations, the substrate 202 has a thickness of about 50-75 microns (μm).

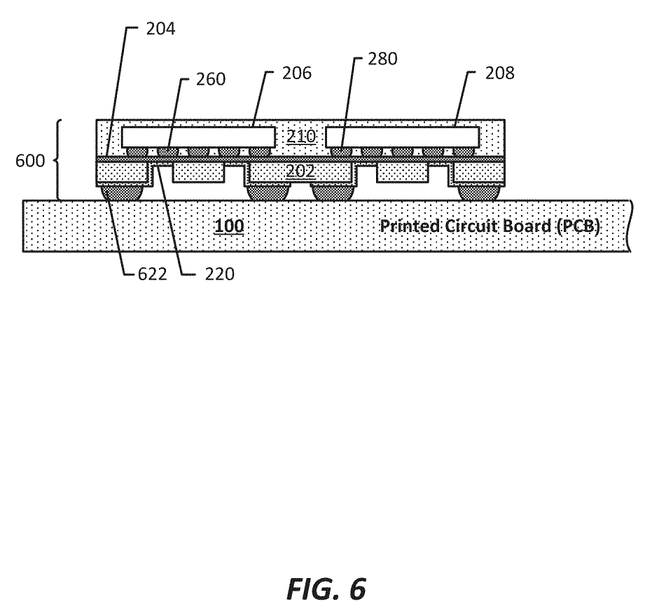

Different implementations may use different plurality of solder interconnects 222. As mentioned above, the plurality of solder interconnects 222 may be landing grid arrays (LGA), which is shown in FIG. 2. In some implementations, the plurality of solder interconnects 222 may be solder balls. FIG. 6 illustrates such an example. FIG. 6 illustrates a device 600 that includes at least one die. The device 600 may be a passive on glass (PoG) device. The device 600 includes a plurality of solder interconnects 622 that is coupled to the plurality of substrate interconnects 220. In some implementations, the device 600 is a low profile device that has an overall thickness of about 225 microns (μm) or less. In some implementations, the device 600 has an overall thickness of about 175-225 microns (μm). The substrate 202 may have a thickness of about 75 microns (μm) or less. In some implementations, the substrate 202 may have a thickness of about 50-75 microns (μm).

It is noted that different implementations may include different numbers of dies. Moreover, different implementations may include different configurations and numbers of passive components (e.g., means for passive functionality).

FIGS. 2-6 illustrate examples of low profiles devices that include passive component(s) and die(s) that can be fabricated at low cost. These devices (e.g., device 200, device 500, device 600) have small forms factors, while still maintaining structural strength despite having a thin or low profile substrate.

In addition to a small factor, another advantage of the devices of the present disclosure is an improvement in performance of the device due to a reduction in the parasitic effects between the die(s) and the passive component(s).

Having described various examples of devices, various processes and methods for fabricating a device will now be described.

### Exemplary Sequence for Fabricating a Passive on Glass (PoG) Comprising a Die

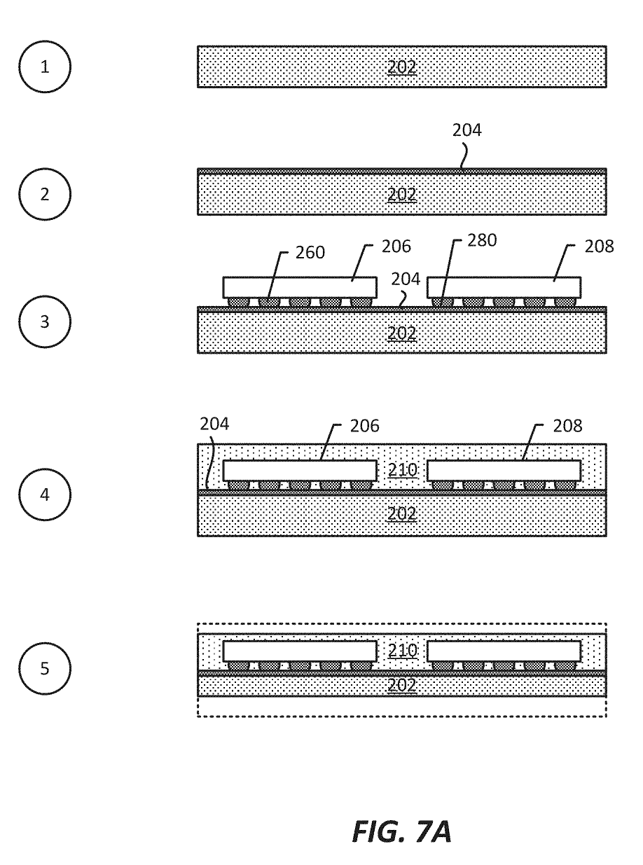

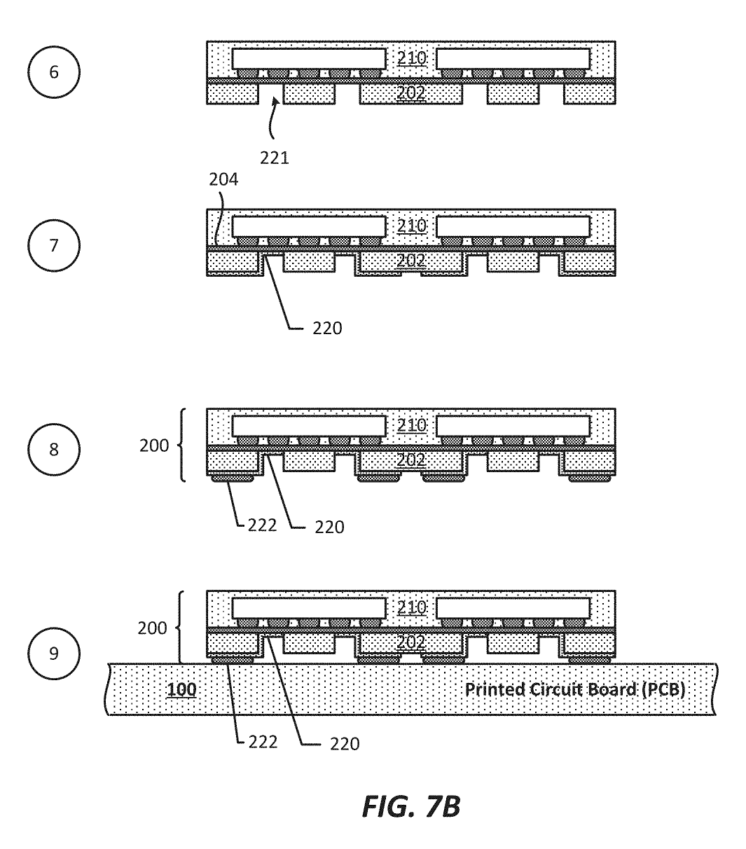

In some implementations, providing/fabricating a device that includes a passive component (e.g., means for passive functionality) and a die includes several processes. FIG. 7 (which includes FIGS. 7A-7B) illustrates an exemplary sequence for providing/fabricating a device that includes a passive component and a die. In some implementations, the sequence of FIGS. 7A-79 may be used to fabricate the device of FIGS. 2-6 and/or other devices described in the present disclosure. However, for the purpose of simplification, FIGS. 7A-7B will be described in the context of fabricating a device of FIG. 2. In particular, FIGS. 7A-7B will be described in the context of fabricating the device 200 of FIG. 2.

It should be noted that the sequence of FIGS. 7A-7B may combine one or more stages in order to simplify and/or clarify the sequence for providing a device. In some implementations, the order of the processes may be changed or modified.

Stage 1, as shown in FIG. 7A, illustrates a state after a substrate 202 is provided. The substrate 202 may comprise a solid material (e.g., single substrate layer, single substrate panel). For example, the substrate 202 may comprise a glass (e.g., block of glass) or silicon (e.g., block of silicon). The substrate 202 may be a wafer, in some implementations, the substrate 202 may consist of a single material (e.g., single layer).

Stage 2 illustrates a state after a plurality of interconnects 204 is formed over the substrate 202. The plurality of interconnects 204 may be configured as one or more passive components (e.g., means for passive functionality, first inductor, second inductor). A plating process may be used to form the plurality of interconnects 204.

Stage 3 illustrates a state after the first die 206 and the second die 208 are coupled to the substrate 202 and the plurality of interconnects 204. The first die 206 is coupled to the substrate 202 and the plurality of interconnects 204 through the plurality of solder interconnects 260. The second die 208 is coupled to the substrate 202 and the plurality of interconnects 204 through the plurality of solder interconnects 280. Different implementations may couple the first die 206 and the second die 208 to the substrate 202 differently (e.g., by using interconnect pillars). In some implementations, a reflow process (e.g., chip attach reflow process) may be used to couple the first die 206 and the second die 208 to the substrate 202. In some implementations, a reflux process may be used after the reflow process.

Stage 4 illustrates a state after an encapsulation layer 210 is fanned over the substrate 202 such that the encapsulation layer 210 at least partially encapsulates the first die 206, the second die 208 and the plurality of interconnects 204. The encapsulation layer 210 may include a mold compound and/or an epoxy fill.

Stage 5 illustrates a state after a portion of the substrate 202 is removed (e.g., grinded away) to thin the substrate 202. Different implementations may remove portions of the substrate 202 differently. In some implementations, portions of the substrate 202 are removed, leaving a substrate 202 that is about 75 microns (μm) or less. Optionally, portions of the encapsulation layer 210 may also be removed (e.g., grinded away), such that the encapsulation layer 210 has a thickness of about 100 microns (μm) or less. In some implementations, the encapsulation layer 210 is removed such that a surface of the encapsulation layer 210 is substantially aligned with a surface (e.g., back side surface) of the first die 206 and/or the second die 208. In some implementations, portions of the encapsulation layer 210 may not need to be removed when the encapsulation layer 210 is formed with the proper amount of encapsulant (e.g., mold compound).

Stage 6, as shown in FIG. 7B, illustrates a state after a plurality of cavities 221 are formed in the substrate 202. The plurality of cavities 221 may be formed by an etching process or a laser process (e.g., laser ablation). The plurality of cavities 221 is formed such that at least some of the plurality of interconnects 204 is exposed through the substrate 202. In some implementations, the plurality of cavities 221 passes through the entire substrate (e.g., substrate 202).

Stage 7 illustrates a state after the plurality of substrate interconnects 220 are formed in the plurality of cavities 221 and a surface of the substrate 202. A plating process may be used to form the plurality of substrate interconnects 220. The plurality of substrate interconnects 220 may be coupled to the plurality of interconnects 204.

Stage 8 illustrates a state after a plurality of solder interconnects 222 is coupled to the plurality of substrate interconnects 220. Examples of the plurality of solder interconnects 222 includes landing grid arrays (LGA) and solder balls. Stage 8 illustrates an example of the device 200 that includes a die. As shown in stage 8, at least of the plurality of cavities 221 are left exposed such that the plurality of cavities 221 substantially passes through the substrate 202.

Stage 9 illustrates a state after the device 200 is coupled to the printed circuit board (PCB) 100 through the plurality of solder interconnects 222.

FIGS. 7A-7B illustrate an example of a low cost fabrication process that enables the fabrication of a low profile device (e.g., Passive on Glass (PoG)) that includes a passive component (e.g., means for passive functionality) and a die. In some implementations, several devices are concurrently fabricated on a wafer, and a singulation process is performed to cut the wafer into individual devices.

### Exemplary Method for Fabricating Passive on Glass (PoG) Comprising a Die

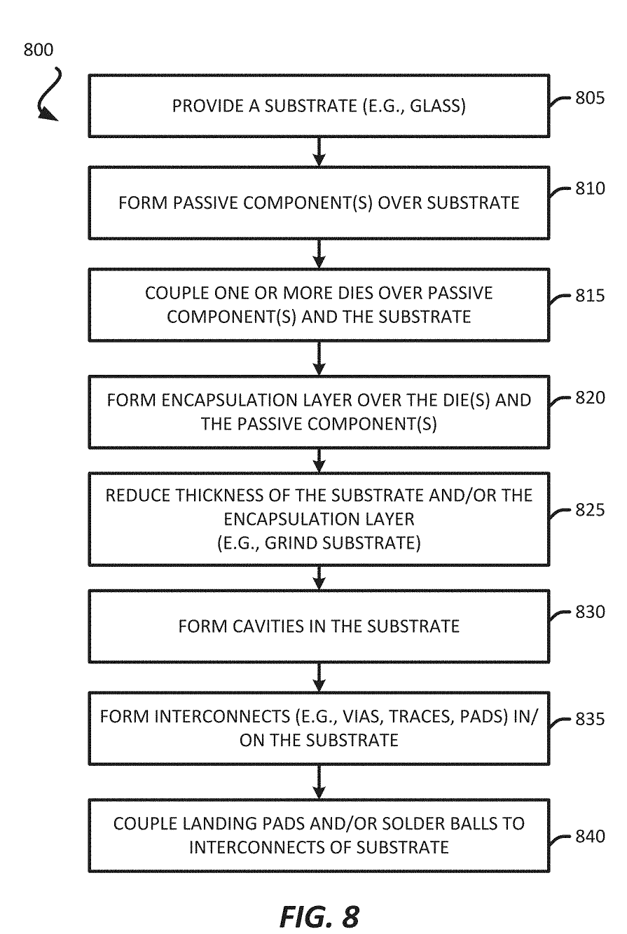

In some implementations, providing fabricating a device that includes a passive component (e.g., means for passive functionality) and a die, includes several processes. FIG. 8 illustrates an exemplary flow diagram of a method for providing/fabricating a device that includes a passive component and a die. In some implementations, the method of FIG. 8 may be used to provide/fabricate the device of FIGS. 2-6 and/or other devices described in the present disclosure. However, for the purpose of simplification, FIG. 8 will be described in the context of providing/fabricating the device of FIG. 2.

It should be noted that the flow diagram of FIG. 8 may combine one or more processes in order to simplify and/or clarify the method for providing a device. In some implementations, the order of the processes may be changed or modified.

The method provides (at 805) a substrate (e.g., substrate 202), The substrate 202 may comprise a solid material (e.g., single layer). For example, the substrate 202 may comprise a glass (e.g., block of glass) or silicon (e.g., block of silicon). The substrate 202 may be a wafer. In some implementations, the substrate 202 may comprise of a solid material (e.g., single layer)

The method forms (at 810) at least one passive component (e.g., means for passive functionality, first inductor, second inductor) over the substrate. In some implementations, the at least one passive component (e.g., means for passive functionality) is defined by a plurality of interconnects (e.g., plurality of interconnects 204). In sonic implementations, forming at least one passive component includes forming (e.g., through a plating process) a plurality of interconnects 204 over the substrate 202.

The method couples (at 815) couples one or more dies to the substrate and to the at least one passive component. For example, the first die 206 and the second die 208 are coupled to the substrate 202 and the plurality of interconnects 204. The first die 206 is coupled to the substrate 202 and the plurality of interconnects 204 through the plurality of solder interconnects 260. The second die 208 is coupled to the substrate 202 and the plurality of interconnects 204 through the plurality of solder interconnects 280. Different implementations may couple the first die 206 and the second die 208 to the substrate 202 differently (e.g., by using interconnect pillars). In some implementations, a reflow process (e.g., chip attach reflow process) may be used to couple the first die 206 and the second die 208 to the substrate 202. In some implementations, a reflux process may be used after the reflow process.

The method forms (at 820) an encapsulation layer (e.g., encapsulation layer 210) over the substrate (e.g., substrate 202) such that the encapsulation layer at least partially encapsulates the die(s) and the at least one passive component (e.g., the plurality of interconnects 204). The encapsulation layer 210 may include a mold compound and/or an epoxy fill.

The method reduces (at 825) the thickness of the substrate (e.g., substrate 202). In some implementations, a grinding process may be used to reduce the thickness of the substrate. In some implementations, portions of the substrate 202 are removed, leaving a substrate that has thickness that is about 75 microns (μm) or less. In some implementations, after reducing the thickness of the substrate, the substrate may have a thickness of about 50-75 microns (μm).

in some implementations, the method may optionally remove portions of the encapsulation layer (e.g., encapsulation layer 210) to reduce the thickness of the encapsulation layer. A grinding process may be used to remove portions of the encapsulation layer. In some implementations, portions of the encapsulation layer may also be removed (e.g., grinded away), such that the encapsulation layer has a thickness of about 100 microns (μm) or less. In some implementations, the encapsulation layer is removed such that a surface of the encapsulation layer is substantially aligned with a surface (e.g., back side surface) of the die(s) (e.g., first die 206, second die 208).

The method forms (at 830) cavities (e.g., plurality of cavities 221 in the substrate (e.g., substrate 202). The cavities may be formed by an etching process or a laser process (e.g., laser ablation). The cavities are formed such that at least some of the plurality of interconnects 204 is exposed through the substrate 202. In some implementations, the cavities pass through the entire substrate (e.g., substrate 202).

The method forms (at 835) substrate interconnects (e.g., plurality of substrate interconnects 220) in the cavities of the substrate (e.g., substrate 202) and a surface of the substrate. A plating process may be used to form the substrate interconnects. The plurality of substrate interconnects 220 may be coupled (e.g., directly coupled) to the plurality of interconnects 204 (which are configured to operate as one or more passive components).

The method couples (at 840) solder interconnects to the substrate interconnects (e.g., plurality of substrate interconnects 220). Examples of the plurality of solder interconnects 222 includes landing grid arrays (LGA) and solder balls.

In some implementations, several devices are concurrently fabricated on a wafer, and a singulation process is performed to cut the wafer into individual devices.

### Exemplary Electronic Devices

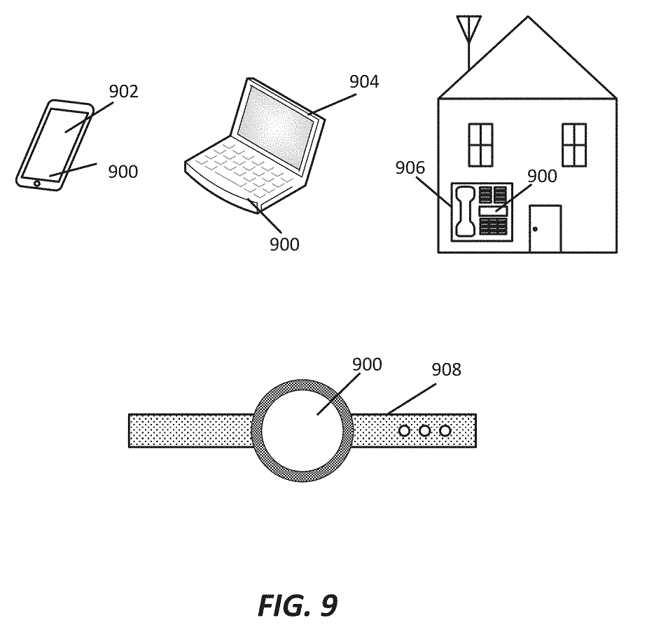

FIG. 9 illustrates various electronic devices that may be integrated with any of the aforementioned integrated device, semiconductor device, integrated circuit, die, interposer, package or package-on-package (PoP). For example, a mobile phone device 902, a laptop computer device 904, a fixed location terminal device 906, a wearable device 908 may include an integrated device 900 as described herein. The integrated device 900 may be, for example, any of the integrated circuits, dies, integrated devices, integrated device packages, integrated circuit devices, device packages, integrated circuit (IC) packages, package-on-package devices described herein. The devices 902, 904, 906, 908 illustrated in FIG. 9 are merely exemplary. Other electronic devices may also feature the integrated device 900 including, but not limited to, a group of devices (e.g., electronic devices) that includes mobile devices, hand-held personal communication systems (PCS) units, portable data units such as personal digital assistants, global positioning system (GPS) enabled devices, navigation devices, set top boxes, music players, video players, entertainment units, fixed location data units such as meter reading equipment, communications devices, smartphones, tablet computers, computers, wearable devices (e.g., watch, glasses), Internet of things (IoT) devices, servers, routers, electronic devices implemented in automotive vehicles (e.g., autonomous vehicles), or any other device that stores or retrieves data or computer instructions, or any combination thereof.

One or more of the components, processes, features, and/or functions illustrated in FIGS. 2, 3, 4, 5, 6, 7A-7B, 8 and/or 9 may be rearranged and/or combined into a single component, process, feature or function or embodied in several components, processes, or functions, Additional elements, components, processes, and/or functions may also be added without departing from the disclosure. It should also be noted that FIGS. 2, 3. 4, 5, 6, 7A-7B, 8 and/or 9 and its corresponding description in the present disclosure is not limited to dies and/or ICs. In some implementations, FIGS. 2, 3, 4, 5, 6, 7A-7B, 8 and/or 9 and its corresponding description may be used to manufacture, create, provide, and/or produce integrated devices. In some implementations, a device may include a die, an integrated device, a die package, an integrated circuit (IC), a device package, an integrated circuit (IC) package, a wafer, a semiconductor device, a package on package (PoP) device, and/or an interposer.

The word “exemplary” is used herein to mean “serving as an example, instance, or illustration.” Any implementation or aspect described herein as “exemplary” is not necessarily to be construed as preferred or advantageous over other aspects of the disclosure. Likewise, the term “aspects” does not require that all aspects of the disclosure include the discussed feature, advantage or mode of operation. The term “coupled” is used herein to refer to the direct or indirect coupling between two objects. For example, if object A physically touches object B, and object B touches object C, then objects A and C may still be considered coupled to one another—even if they do not directly physically touch each other.

Also, it is noted that various disclosures contained herein may be described as a process that is depicted as a flowchart, a flow diagram, a structure diagram, or a block diagram. Although a flowchart may describe the operations as a sequential process, many of the operations can be performed in parallel or concurrently. In addition, the order of the operations may be re-arranged. A process is terminated when its operations are completed.

The various features of the disclosure described herein can be implemented in different systems without departing from the disclosure. It should be noted that the foregoing aspects of the disclosure are merely examples and are not to be construed as limiting the disclosure. The description of the aspects of the present disclosure is intended to be illustrative, and not to limit the scope of the claims. As such, the present teachings can be readily applied to other types of apparatuses and many alternatives, modifications, and variations will be apparent to those skilled in the art.

1. A device comprising:
a single substrate layer comprising:
a first surface;
a second surface being substantially opposite to the first surface; and
a cavity that passes through the second surface of the single substrate;
a plurality of interconnects over the first surface of the single substrate layer, the plurality of interconnects configured to operate as at least one passive component;
a substrate interconnect coupled to the plurality of interconnects, wherein the substrate interconnect is formed (i) partially in the cavity of the single substrate layer such that the cavity is partially unfilled, and (ii) over the second surface of the single substrate layer such that the substrate interconnect travels at least laterally along the second surface of the single substrate;
a first die coupled to the single substrate layer and the plurality of interconnects; and
an encapsulation layer that at least partially encapsulates the first die and the plurality of interconnects configured to operate as at least one passive component.

2. The device of claim 1, wherein the single substrate layer, the first die and the encapsulation layer comprise an overall thickness of about 225 microns (μm) or less.

3. The device of claim 1, wherein the single substrate layer comprises a thickness of about 50-75 microns (μm).

4. The device of claim 1, wherein the encapsulation layer comprises a thickness of about 100 microns (μm) or less.

5. The device of claim 1, wherein the single substrate layer comprises a single layer of glass or a single layer of silicon.

6. The device of claim 1, wherein a portion of the cavity that substantially passes through the single substrate layer.

7. The device of claim 1, wherein the at least one passive component comprises an inductor.

8. The device of claim 1, further comprising a second die coupled to the single substrate layer and the plurality of interconnects.

9. The device of claim 8, wherein the plurality of interconnects is configured to operate as a first inductor and a second inductor, the first inductor coupled to the first die, and the second inductor coupled to the second die,

10. The device of claim 1, wherein the device is incorporated into a. device selected from the group consisting of a music player, a video player, an entertainment unit, a navigation device, a communications device, a mobile device, a mobile phone, a smartphone, a personal digital assistant, a fixed location terminal, a tablet computer, a computer, a wearable device, an Internet of things (IoT) device, a laptop computer, a server, and a device in an, automotive vehicle.

11. An apparatus comprising:
a single substrate layer;
a means for passive functionality located over the single substrate layer;
a first die coupled to the single substrate layer and the means for passive functionality, the first die comprising a plurality of solder interconnects that is directly coupled to the means for passive functionality; and
an encapsulation layer that at least partially encapsulates the first die and the means for passive functionality.

12. The apparatus of claim 11, wherein the single substrate layer, the first die and the encapsulation layer comprise an overall thickness of about 225 microns (μm) or less.

13. The apparatus of claim 11, wherein the single substrate layer comprises a thickness of about 50-75 microns (μm).

14. The apparatus of claim 11, wherein the encapsulation layer comprises a thickness of about 100 microns (μm) or less.

15. The apparatus of claim 11, wherein the single substrate layer comprises a single layer of glass or a single layer of silicon.

16. The apparatus of claim 11, further comprising a cavity that substantially passes through the single substrate layer.

17. The apparatus of claim 11, wherein the means for passive functionality comprises an inductor.

18. The apparatus of claim 11, further comprising a second die coupled to the single substrate layer and the means for passive functionality.

19. The apparatus of claim 18, wherein the means for passive functionality comprises a first inductor and a second inductor, the first inductor coupled to the first die, and the second inductor coupled to the second die.

20. The apparatus of claim 11, wherein the apparatus is incorporated into a device selected from the group consisting of a music player, a video player, an entertainment unit, a navigation device, a communications device, a mobile device, a mobile phone, a smartphone, a personal digital assistant, a fixed location terminal, a tablet computer, a computer, a wearable device, an Internet of things (IoT) device, a laptop computer, a server, and a device in an automotive vehicle.

21. A method for fabricating a device, comprising:
providing a single substrate layer comprising a first surface and a second surface being substantially opposite to the first surface;
forming a plurality of interconnects over the first surface of the single substrate layer, wherein forming the plurality of interconnects forms interconnects that are configured to operate as at least one passive component;
coupling a first die to the single substrate layer and the plurality of interconnects; and
forming an encapsulation layer that at least partially encapsulates the first die and the plurality of interconnects configured to operate as at least one passive component;
forming a cavity in the single substrate such that the cavity passes through the second surface of the single substrate; and
forming a substrate interconnect (i) partially in the cavity of the single substrate layer such that the cavity is partially unfilled, and (ii) over the second surface of the single substrate layer such that the substrate interconnect travels at least laterally along the second surface of the single substrate, wherein the substrate interconnect is formed such that the substrate interconnect is coupled to the plurality of interconnects.

22. The method of claim 21, wherein the single substrate layer, the first die and the encapsulation layer comprise an overall thickness of about 225 microns (μum) or less.

23. The method of claim 21, wherein the single substrate layer comprises a thickness of about 75 microns (μm) or less.

24. The method of claim 21, wherein the encapsulation layer comprises a thickness of about 100 microns (μm) or less.

25. The method of claim 21, wherein the single substrate layer comprises a single layer of glass or a single layer of silicon.

26. The method of claim 21, wherein forming the cavity comprises forming a cavity that substantially passes through the single substrate layer.

27. The method of claim 21, wherein the at least one passive component comprises an inductor.

28. The method of claim 21, further comprising coupling a second die to the single substrate layer and the plurality of interconnects.

29. The method of claim 21, further reducing the thickness of the single substrate layer.

30. The method of claim 21, wherein the package on package (PoP) device is incorporated into a device selected from the group consisting of a music player, a video player, an entertainment unit, a navigation device, a communications device, a mobile device, a mobile phone, a smartphone, a personal digital assistant, a fixed location terminal, a tablet computer, a computer, a wearable device, an Internet of things (IoT) device, a laptop computer, a server, and a device in an automotive vehicle.
